(19) United States
(12) Patent Application Publication
(10) Pub. No.: US 2025/0048770 A1
(43) Pub. Date: Feb. 6, 2025

(54) PHOTOVOLTAIC CELL ELEMENT, PHOTOVOLTAIC CELL AND METHODS FOR MANUFACTURING SUCH ELEMENT AND CELL

(71) Applicant: COMMISSARIAT A L'ENERGIE ATOMIQUE ET AUX ENERGIES ALTERNATIVES, Paris (FR)

(72) Inventors: Nicolas ENJALBERT, Grenoble Cedex 09 (FR); Samuel HARRISON, Grenoble Cedex 09 (FR); Christine DENIS, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/719,589

(22) PCT Filed: Dec. 6, 2022
(86) PCT No.: PCT/EP2022/084601

§ 371 Date: Jun. 13, 2024

(30) Foreign Application Priority Data
Dec. 15, 2021 (FR) 2113566

(51) Int. Cl. H01L 31/18; H01L 31/0352

(52) U.S. Cl. CPC H01L 31/186; H01L 31/0352

(57) ABSTRACT

A photovoltaic cell element includes a photovoltaic cell substrate configured to generate electrons upon reception of a light radiation, an outer boundary and an inner boundary delimiting the substrate. The element has no material outside the outer boundary and inside the inner boundary, and the substrate has a primer trench formed at least partially over the surface of the substrate.

### TECHNICAL FIELD OF THE INVENTION

The present invention relates to the field of photovoltaic cells. It finds a particularly advantageous application in making photovoltaic cells having non-conventional geometric shapes such as shapes having a recessed inner portion, for example rings.

### PRIOR ART

In general, a photovoltaic cell converts part of the light radiation into electrical energy. A photovoltaic cell comprises a substrate configured to generate electrons upon reception of a light radiation, a first electrically-conductive structure over a first surface of the substrate and a second electrically-conductive structure over a second surface of the substrate, opposite to the first surface. Each surface layer generally enabling the favoured collection of a carrier type (electrons or holes). The primarily used substrate comprises silicon.

Mention may be made of some very high efficiency photovoltaic cells, for example HET-type (i.e. a heterojunction type) and TOPCon-type (“Tunnel Oxide Passivated Contact”) cells. In particular, a HET-type cell is a cell comprising a layer of a crystalline substrate and at least one hydrogenated amorphous silicon layer in contact with the crystalline substrate layer.

Devices integrating photovoltaic cells are numerous, and require photovoltaic cells with very variable sizes and with shapes that are very variable too.

Hence, there is a general need consisting in making photovoltaic cells with non-conventional shapes. In general, the conventional shapes of photovoltaic cells are disks or squares, with sharp or rounded edges.

One might also be brought to use photovoltaic cells for diverse and various devices, such as rolling shutters or connected objects, in particular for small-size devices, such as calculators, etc.

There are a lot of industrial solutions for cutting photovoltaic cells. The most used technology remains the use of laser to generate a trench in silicon, followed by a cut with mechanical cleavage, i.e. a physical separation of the two portions of the cell.

However, the cut results in electrical losses, which are relatively significant for high-efficiency cells. This is even truer for small-size cells, or the effect of the cut edge becomes very significant with regards to the total surface of the cell. Indeed, it is observed that the more the size of a cell obtained by cutting is reduced, and the more the electrical losses will increase. Moreover, the higher incident energy of the laser used for cutting, the more the final performances of the cell will be degraded. Indeed, the impact of the temperature generated by the laser is considerable, and the use of a high-power laser, necessary to ensure a good cut, does not allow obtaining cells with enough electrical performances. An optimisation of the cut may consist in using successive passes to reduce the impact of each laser shot. Nevertheless, a final degradation is observed, which is even more considerable as the trench to be generated for a clean cut should be deep.

An object of the invention consists in proposing means for providing a photovoltaic cell element having satisfactory performances.

Another object consists in providing means for providing a photovoltaic cell element suited to be integrated within a small-size device.

### SUMMARY OF THE INVENTION

To achieve these objectives, a method for manufacturing at least one photovoltaic cell element is proposed, comprising:
a provision of a photovoltaic cell substrate configured to generate electrons upon reception of a light radiation; and
a generation of a so-called outer trench over a surface of the substrate to form an outer boundary delimiting a first portion of the substrate outside the outer boundary.

The method further comprises:
a generation of a so-called inner trench over the surface of the substrate to form a closed inner boundary delimiting a second portion of the substrate inside the inner boundary and a third portion of the substrate between the outer and inner boundaries;
a generation of a primer trench over the surface of the substrate, the primer trench being formed, at least partially in at least one portion of the substrate from among the second and third portions of the substrate; and
a so-called inner separation comprising a mechanical separation of the second portion with the third portion so as to obtain at least one photovoltaic cell element from the third portion of the substrate.

Thus, a method is provided which is particularly suited to obtain photovoltaic cell elements having complex shapes, in particular non-conventional geometric shapes, such as a round, a triangle, a ring, a hexagon, etc. Furthermore, such a method allows obtaining elements having a material-free portion, for example at the core of the element. The proposed method allows obtaining a possibly complex shape, for example recessed, with a considerably reduced risk of breakage. Moreover, this method including a primer trench facilitates in particular the mechanical separation of the second and third portions, and therefore allows for a significant reduction of the trench depth necessary for the separation of the different portions of the substrate. Consequently, the incident laser power necessary to make the inner and/or outer trench or trenches is also considerably reduced. Thus, the proposed method allows reducing the degradation of the substrate caused by the power of the laser. Ultimately, the proposed method thus allows improving the performances, in particular the efficiency of photovoltaic cells having complex shapes.

According to another aspect, a method for manufacturing a photovoltaic cell is proposed, comprising a manufacture of at least one photovoltaic cell element as defined hereinbefore and at least one metallisation, performed before or after the inner separation, the metallisation comprising a formation of a first electrically-conductive structure over a first surface of the substrate and of a second electrically-conductive structure over a second surface of the substrate, opposite to the first surface.

According to another aspect, a photovoltaic cell element is proposed, comprising a photovoltaic cell substrate configured to generate electrons upon reception of a light radiation, an outer boundary and an inner boundary delimiting the substrate, the element having no material outside the outer boundary and inside the inner boundary and the substrate comprises a primer trench formed at least partially over a surface of the substrate.

According to another aspect, a photovoltaic cell is proposed, comprising a photovoltaic cell element as defined hereinbefore, and a first electrically-conductive structure located over a first surface of the substrate and a second electrically-conductive structure located over a second surface of the substrate, opposite to the first surface.

### BRIEF DESCRIPTION OF THE FIGURES

The aims, objects, as well as the features and advantages of the invention will appear better from the detailed description of embodiments and implementations of the latter, illustrated by the following appended drawings wherein:

FIGS. 1 to 9, schematically illustrate the main steps of an implementation of a method for manufacturing a photovoltaic cell element; and

FIGS. 10 to 18, schematically illustrate other implementations of a method for manufacturing a photovoltaic cell element.

The drawings are provided by way of example and are not intended to limit the scope of the invention. They constitute diagrammatic views intended to ease the understanding of the invention and are not necessarily to the scale of practical 20) applications.

### DETAILED DESCRIPTION OF THE INVENTION

Before starting a detailed review of embodiments of the invention, optional features that may be used in combination or alternatively are set out hereinafter:
According to one example, the primer trench opens into a main area of the inner trench and the inner separation comprises a generation of a crack which propagates along the primer trench and along the inner trench.
According to one example, the primer trench extends in the third portion of the substrate while opening into the outer trench.
According to one example, the primer trench is partially formed in the second and third portions of the substrate.
According to one example, the primer trench extends in the second portion of the substrate from the main area towards a secondary area of the inner trench, the primer trench further opening into the secondary area.
According to one example, the primer trench extends in the second and third portions of the substrate from a first area of the outer trench towards a second area of the outer trench, the primer trench further opening into the first and second areas.
According to one example, the inner separation comprises a mechanical separation of the third portion of the substrate into at least two distinct parts of the substrate so as to obtain at least two photovoltaic cell elements respectively from said at least two distinct parts of the substrate.
According to one example, the method comprises a connection between at least two distinct parts of the substrate to provide the same photovoltaic cell element.
According to one example, the primer trench is partially formed in the third portion of the substrate while opening into the outer trench and the inner separation comprises a generation of a crack which propagates along the inner trench.
According to one example, at least one trench from among the outer, inner and primer trenches, is a trench made in a non-through manner within the substrate.
According to one example, the generation of the inner trench forms a closed inner boundary.
According to one example, the generation of the outer trench forms a closed outer boundary.
According to one example, the generation of the primer trench creates a partially rectilinear primer trench.
According to one example, the method comprises, after the generation of the outer trench and before the generation of the primer trench, a so-called outer separation, comprising a mechanical separation of the first portion with the third portion.
According to one example, the method comprises, after the inner separation, a so-called outer separation, comprising a mechanical separation of the first portion with the third portion.
According to one example, the method comprises, before the outer separation, a generation of an initial trench over the surface of the substrate, in the first portion of the substrate and opening into the outer trench.
According to one example, the method comprises, after provision of the substrate and before the inner separation, a generation of an additional trench over the surface of the substrate and in the second portion of the substrate to form an additional boundary delimiting a fourth portion of the substrate inside the additional boundary, and a mechanical separation of the fourth portion with the second portion.
According to one example, the primer trench opens into the inner trench and into the additional trench.

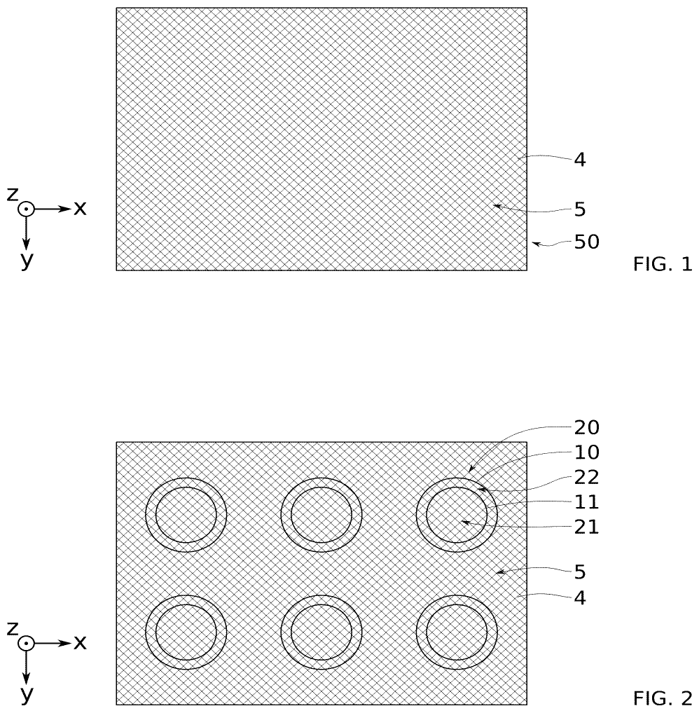

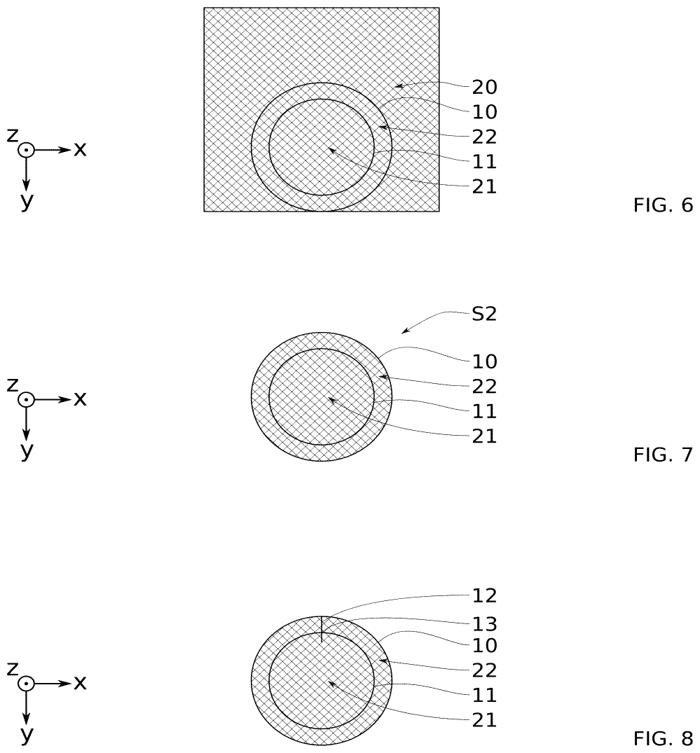

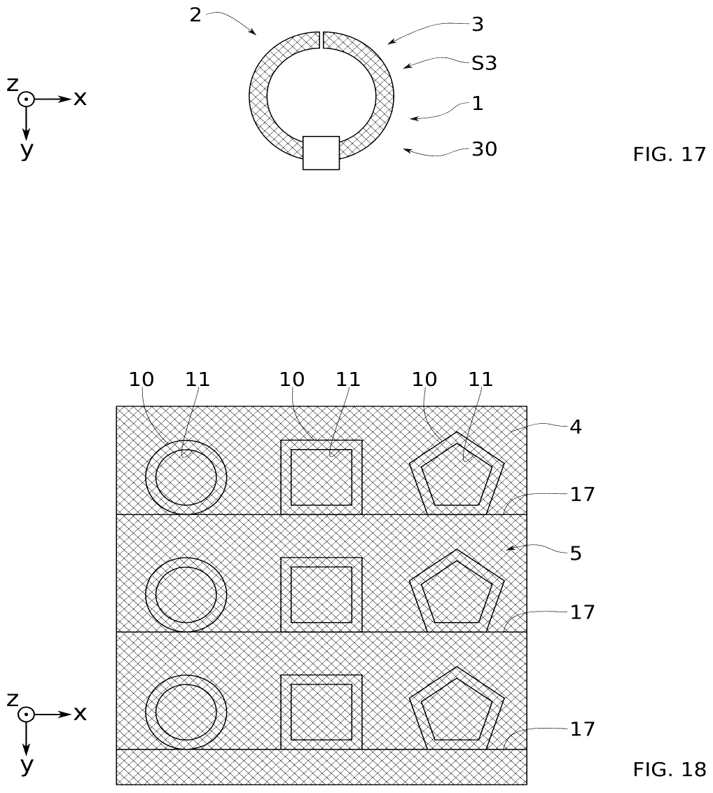

In FIGS. 1 to 18, the main steps of a method for manufacturing at least one photovoltaic cell element 1 to 3 have been represented. A cell element 1 to 3 is intended to manufacture a photovoltaic cell 30, in particular a HET or TOPCon type very high efficiency cell. In general, the method includes a provision of a photovoltaic cell substrate 4 configured to generate electrons upon reception of a light radiation, illustrated in FIG. 1. The dimensions of the substrate 4, in length according to an axis X, and in width according to an axis Y perpendicular to the axis X, are at least larger than those of the elements 1 to 3 to be manufactured. The substrate 4 may originate from a “wafer”, i.e. a slice or a plate of a monocrystalline semiconductor material, preferably silicon, used to manufacture microelectronics components. After a cleaning step, amorphous silicon layers may be deposited over each surface of the trench. For example, the thickness of the substrate 4, according to an axis Z perpendicular to the axes X and Y, is comprised between 70 and 200 μm.

Furthermore, the method includes a generation of a so-called outer 10 trench and a generation of a so-called inner trench 11, as illustrated in FIG. 2.

The outer trench 10 is made over a first surface 5 of the substrate 4 to form an outer boundary delimiting a first portion 20 of the substrate 4 outside the outer boundary. The inner trench 11 is made over the first surface 5 of the substrate 4 to form an inner boundary delimiting a second portion 21 of the substrate 4 inside the inner boundary and a third portion 22 of the substrate 4 between the outer and inner boundaries. The inner trench 11 may be made after, or before, making the outer trench 10.

In FIG. 2, an example wherein several inner trenches 11 and several outer 30) trenches 10 are generated, so as to generate several third portions 22 from the same substrate 4.

More particularly, the method comprises a generation of a primer trench 12 over the first surface 5 of the substrate 4, as illustrated in FIGS. 8 and 10 to 15, the primer trench 12 being formed at least partially in at least one portion of the substrate 4 from among the second and third portions 21, 22 of the substrate 4. The primer trench 12 is intended to facilitate a mechanical separation of the second and third portions 21, 22. The primer trench 12 may be made before or after making the outer 10 and inner 11 trenches, or after one of the outer 10 or inner 11 trenches.

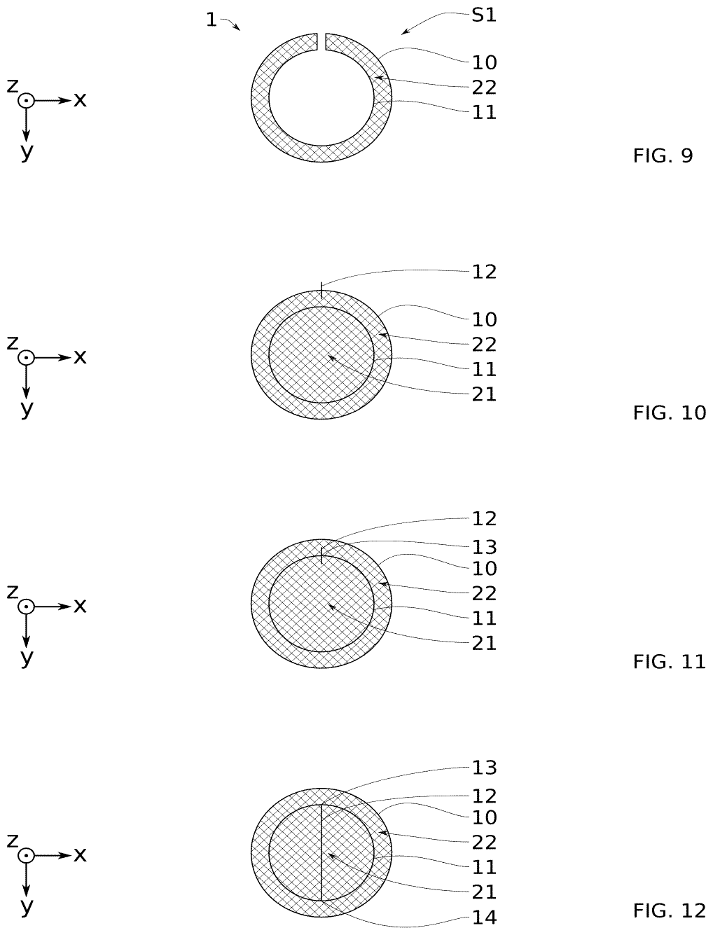

The method further comprises a so-called inner separation S1, as illustrated in FIG. 9. The inner separation S1 comprises a mechanical separation of the second portion 21 with the third portion 22 so as to obtain at least one photovoltaic cell element 1 to 3 from the third portion 22 of the substrate 4. In general, the inner separation S1 comprises a generation of a crack which propagates at least along the inner trench 11 and results in the physical separation of the second portion 21 with the third portion 22. In other words, a mechanical separation results in a physical separation of two elements. A physical separation of two elements allows obtaining two elements distinct from each other. Hence, the inner separation S1 results in a physical separation of the second portion 21 with the third portion 22 so as to obtain a third portion 22 distinct from the second portion 21.

The primer trench 12 allows facilitating the inner separation S1. More particularly, the primer trench 12 allows limiting the formation of crackings at the third portion 22, also referred to as active portion, i.e. the portion of the substrate 4 intended to manufacture the photovoltaic cell element 1 to 3. A cracking corresponds to an undesirable breaking at the surface of the substrate 4, allows considerably reducing the 20) capacities of the third portion 22 or breaking up the photovoltaic cell 1 to 3 in the case where the crackings are too significant. Indeed, during the inner separation S1 and in the absence of the primer trench 12, crackings may propagate at the third portion 22. Thus, the primer trench 12 allows limiting the breakage rate of the third portion 22 during the inner separation S1.

Thus, an element 1 to 3 that may have a non-conventional geometric shape, such as a round, a triangle, a ring, a hexagon, etc., is obtained, as illustrated in FIG. 18. By conventional geometric shape of a photovoltaic cell, it should be understood a quadrilateral-like shape, such as a square, a rectangle or a lozenge. Furthermore, it is possible to easily obtain an element having a recessed portion, i.e. a material-free clear space, at the core of the element 1 to 3.

In general, at least one trench from among the outer 10, inner 11 and primer 12 trenches, is a trench made in a non-through manner within the substrate 4. Preferably, the trenches 10 to 12 are non-through within the substrate 4. By non-through trench, it should be understood a trench having a depth within the substrate 4, according to the axis Z, comprised between ⅓ and ¾ of the thickness of the substrate 4, preferably comprised between ½ and ¾ of the thickness of the substrate 4. For example, a width of a trench 10 to 12, considered according to the axis X, may be comprised between 5 μm and 50 μm, preferably between 10 μm and 25 μm. Moreover, the primer trench 12 allows avoiding making through inner and outer trenches 10, 11, or more generally allows reducing the depth of the inner and outer trenches 10 and 11 necessary for a facilitated separation of the second and third portions 21 and 22 while minimising the generation of undesirable crackings or breakages and the degradation of the performances of the photovoltaic cells by the method for generating the trenches. For example, the trenches 10 to 12 are made using a laser. Hence, the primer trench 12 allows reducing the energy of the laser used to make the trenches 10 to 12 and limiting the associated degradation. According to one implementation, the inner and outer trenches 10, 11 are made using a laser whose wavelength is green, for example the wavelength is equal to 532 nm, the speed is comprised between 10 and 25 mm/s and the power is comprised between 2.2 and 2.8 W. Advantageously, the outer and inner trenches 10, 11 are generated through four to eight successive passes of the laser. To make the primer trench 12, it is possible to use a laser whose wavelength is green, for example the wavelength is equal to 532 nm, the speed is comprised between 20 and 25 mm/s, the power is comprised between 2.9 and 3.1 W, with two to three successive passes of the laser. Furthermore, the primer trench 12 allows limiting the number of passes of the laser to make the trenches 10 to 12 to limit undesirable degradations over the substrate 4. For example, it is possible to use laser powers higher than 3 W. Besides reducing the depth of the outer 10 and inner 11 trenches, the generation of the primer trench 12 allows reducing the depth of the primer trench 12 itself, and therefore reducing the energy of the used laser by reducing the number of passes. Hence, the primer trench 12 allows reducing the energy of the used laser, in particular by reducing 25 the number of passes and by increasing the speed of passes, while preserving the electrical performances of the third portion 22.

For example, the generation of the inner trench 11 forms a closed inner boundary. Advantageously, the generation of the outer trench 10 forms a closed outer boundary. According to one implementation, the generation of the primer trench 12 creates a partially rectilinear primer trench 12. Preferably, the primer trench 12 is rectilinear. Thus, it is not necessary to stop the laser shot to change direction.

In FIGS. 8 and 11 to 15, different embodiments of a primer trench 12 have been represented, wherein the primer trench 12 opens into a main area 13 of the inner trench 11 and the inner separation S1 comprises a generation of a crack which propagates along the primer trench 12 and along the inner trench 11. In general, the generation of the primer trench 12 may be carried out between the step of generating several third portions 22 from the same substrate 4, as illustrated in FIG. 2, and the so-called outer separation step, illustrated in FIG. 7.

In FIG. 8, an embodiment has been represented wherein the primer trench 12 extends in the third portion 22 of the substrate 4 while opening into the outer trench 10.

In FIG. 11, the primer trench 12 is partially formed in the second and third portions 21, 22 of the substrate 4.

In FIG. 12, the primer trench 12 extends in the second portion of the substrate from the main area 13 towards a secondary area 14 of the inner trench 11, the primer trench 12 further opening into the secondary area 14.

According to another implementation, represented in FIG. 10, the primer trench 12 is partially formed in the third portion 22 of the substrate 4 while opening into the outer trench 10 and the inner separation S1 comprises a generation of a crack which propagates along the inner trench 11.

In FIGS. 15 to 17, an implementation of the method has been represented wherein, the primer trench 12 extends in the second and third portions 21, 22 of the substrate from a first area 15 of the outer trench 10 towards a second area 16 of the outer trench 10, the primer trench 12 further opening into the first and second areas 15, 16.

Furthermore, the inner separation S1 comprises a mechanical separation of the third portion 22 of the substrate 4 into at least two distinct parts 23, 24 of the substrate 4 so as to obtain at least two photovoltaic cell elements 2, 3 respectively from said at least two distinct parts 23, 24 of the substrate 4.

The method may further comprise a connection S3 between at least two distinct parts 23, 24 of the substrate 4 to provide the same photovoltaic cell element 1.

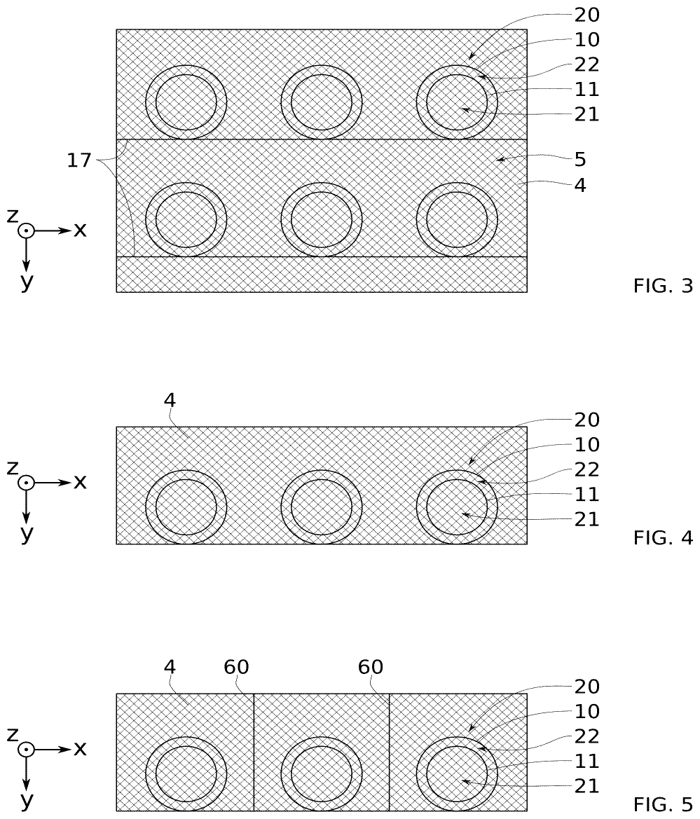

In FIG. 7, a so-called outer separation S2 has been represented, comprising a mechanical separation of the first portion 20 with the third portion 22. In general, the outer separation S2 comprises a generation of a crack which propagates at least along the outer trench 10 and results in the physical separation of the first portion 20 with the third portion 22. Hence, the outer separation S2 results in a physical separation of the first portion 20 with the third portion 22 so as to obtain a third portion 22 distinct from the first portion 20. The outer separation S2 is carried out after the generation of the outer trench 11. Preferably, the outer separation S2 is carried out before the generation of the primer trench 12. In order to facilitate the physical separation of the first portion 20 with the third portion 22, the method may comprise, before the outer separation S2, a generation of an initial trench 17 over the first surface 5 of the substrate 4, in the first portion 20 of the substrate 4 and opening into the outer trench 11, as illustrated in FIGS. 3 and 18. The initial trench 17 provides a local break-up primer for facilitating the propagation of the crack along the initial trench 17. Hence, the initial trench 17 facilitates the physical separation of the first portion 20 of the substrate 4, for example to obtain a sample comprising a substrate 4, several inner trenches 11 and several outer trenches 10, as illustrated in FIG. 4. The generation of the initial trench 17 may be performed before, or after, the generation of the inner trench 11. Preferably, the generation of the inner trench 11 is performed after the outer separation S2. Indeed, this allows limiting the propagations of undesirable crackings and facilitating the inner separation S1.

In FIG. 5, an implementation has been represented, wherein the method comprises a generation of additional trenches 60 to facilitate the separation of the substrate 4 into several devices, each device comprising at least one third portion 22.

Preferably, the generation of the primer trench 12 is carried out during the step of obtaining a sample, as illustrated in FIG. 4, or during the step of generating additional trenches 60, illustrated in FIG. 5.

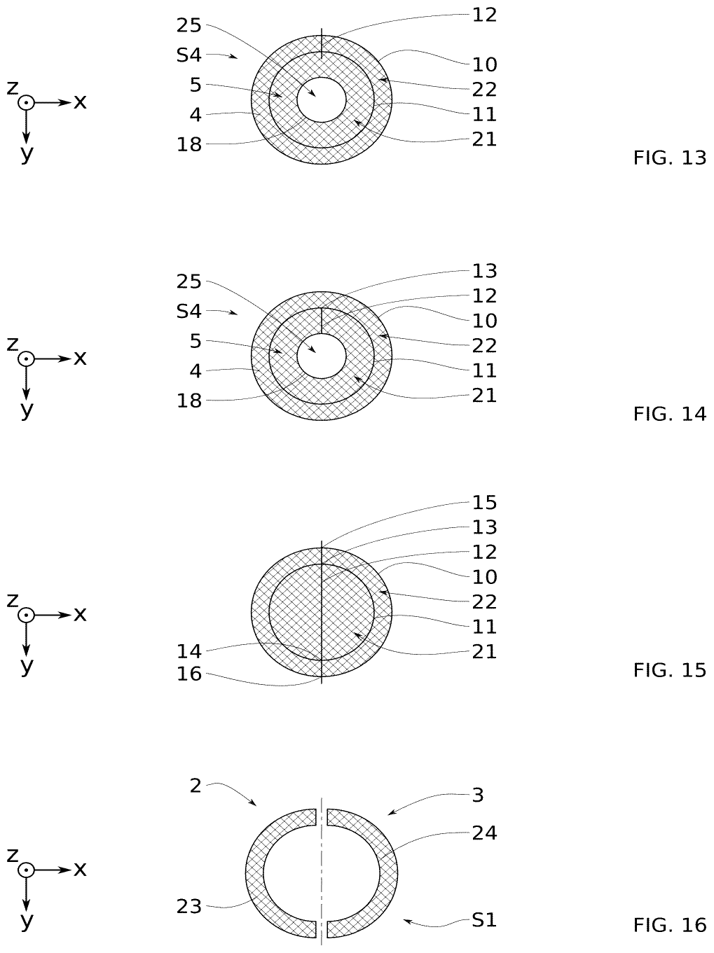

In FIGS. 13 and 14, other implementations are also represented, wherein the method comprises, after provision of the substrate 4 and before the generation of the primer trench 12, a generation of an additional trench 18 over the surface 5 of the substrate 4 and in the second portion 21 of the substrate 4 to form an additional boundary delimiting a fourth portion 25 of the substrate 4 inside the additional boundary, and a mechanical separation S4 of the fourth portion 25 with the second portion 21. Thus, during the inner separation S1, the crack may propagate inside the clear space left after removal of the fourth portion 25. The formation of undesirable crackings within the third portion 22 is further prevented. Preferably, the primer trench 12 opens into the inner trench 11 and into the additional trench 18, as illustrated in FIG. 14. Thus, the propagation of the crack is promoted in the clear space that does not correspond to an area of interest for manufacturing a photovoltaic cell element 1 to 3.

The method for manufacturing a photovoltaic cell element 1 to 3 allows manufacturing an element 1 to 3 comprising a photovoltaic cell substrate 4 configured to generate electrons upon reception of a light radiation, an outer boundary and an inner boundary delimiting the substrate 4, in particular a surface 5 of the substrate 4, so that the element 1 to 3 has no material outside the outer boundary and inside the inner boundary and the substrate comprises a primer trench 12 formed at least partially over the surface 5 of the substrate.

Such an element 1 to 3 allows providing a method for manufacturing a photovoltaic cell 30. The method for manufacturing the cell 30 comprises a manufacture of at least one photovoltaic cell element 1 to 3 and a metallisation, after provision of the substrate 4, the metallisation comprising a formation of a first electrically-conductive structure over a first surface 5 of the substrate 4 and of a second electrically-conductive structure over a second surface 50 of the substrate 4, opposite to the first surface 5. The first and second electrically-conductive structures are not represented for simplicity. The metallisation may be performed before the generation of the inner 11 and outer 10 trenches, or after the manufacture of the photovoltaic cell element 1 to 3. For example, the first electrically-conductive structure may be made based on silver, printed over the first surface 5, by screen-printing. The second electrically-conductive structure may be a transparent conductive layer over the second surface 50.

The means that have just been described allow manufacturing photovoltaic cell elements having non-conventional shapes, in particular a recessed one. Such elements are particularly suited to manufacture photovoltaic cells, in particular at very high rates, intended to be integrated into small-size devices, such as smartphones, etc.

1. A method for manufacturing at least one photovoltaic cell element, comprising:
providing a photovoltaic cell substrate configured to generate electrons upon reception of a light radiation;
forming an outer trench over a surface of the substrate to form a closed outer boundary delimiting a first portion of the substrate outside the outer boundary;
forming an inner trench over the surface of the substrate to form a closed inner boundary delimiting a second portion of the substrate inside the inner boundary and a third portion of the substrate between the outer and inner boundaries;
forming a primer trench over the surface of the substrate, the primer trench being formed, at least partially in at least one portion of the substrate from among the second and third portions of the substrate to facilitate a mechanical separation of the second and third portions; and
producing an inner separation comprising a mechanical separation resulting in a physical separation of the second portion from the third portion so as to obtain at least one photovoltaic cell element from the third portion of the substrate.

2. The method according to claim 1, wherein the primer trench opens into a main area of the inner trench and the inner separation comprises a generation of a crack which propagates along the primer trench and along the inner trench.

3. The method according to claim 2, wherein the primer trench extends in the third portion of the substrate while opening into the outer trench.

4. The method according to claim 2, wherein the primer trench is partially formed in the second and third portions of the substrate.

5. The method according to claim 2, wherein the primer trench extends in the second portion of the substrate from the main area towards a secondary area of the inner trench, the primer trench further opening into the secondary area.

6. The method according to claim 1, wherein the primer trench extends in the second and third portions of the substrate from a first area of the outer trench towards a second area of the outer trench, the primer trench further opening into the first and second areas.

7. The method according to claim 6, wherein the inner separation comprises a mechanical separation resulting in a physical separation of the third portion of the substrate into at least two distinct parts of the substrate so as to obtain at least two photovoltaic cell elements respectively from the at least two distinct parts of the substrate.

8. The method according to claim 7, comprising forming a connection between the at least two distinct parts of the substrate to provide the same photovoltaic cell element.

9. The method according to claim 1, wherein the primer trench is partially formed in the third portion of the substrate while opening into the outer trench and the inner separation comprises a generation of a crack which propagates along the inner trench.

10. The method according to claim 1, wherein at least one trench from among the outer, inner and primer trenches is a trench made in a non-through manner within the substrate.

11. The method according to claim 1, wherein forming the primer trench comprises creating a partially rectilinear primer trench.

12. The method according to claim 1, comprising, after forming the outer trench and before forming the primer trench, producing an outer separation comprising a mechanical separation resulting in a physical separation of the first portion from the third portion.

13. The method according to claim 1, comprising, after producing the inner separation, producing an outer separation comprising a mechanical separation resulting in a physical separation of the first portion from the third portion.

14. The method according to claim 12, comprising, before producing the outer separation, forming an initial trench over the surface of the substrate in the first portion of the substrate and opening into the outer trench.

15. The method according to claim 1, comprising, after providing the substrate and before producing the inner separation, forming an additional trench over the surface of the substrate and in the second portion of the substrate to form an additional boundary delimiting a fourth portion of the substrate inside the additional boundary, and a mechanical separation resulting in a physical separation of the fourth portion from the second portion.

16. The method according to claim 15, wherein the primer trench opens into the inner trench and into the additional trench.

17. A method for manufacturing a photovoltaic cell, comprising manufacturing at least one photovoltaic cell element according to claim 1 and at least one metallisation before or after producing the inner separation, the metallisation comprising forming a first electrically-conductive structure over a first surface of the substrate and a second electrically-conductive structure over a second surface of the substrate opposite to the first surface.

18. A photovoltaic cell element, comprising:
a photovoltaic cell substrate configured to generate electrons upon reception of a light radiation, and
an outer boundary and an inner boundary delimiting a surface of the substrate,
wherein the element has no material outside the outer boundary and inside the inner boundary and the substrate comprises a primer trench formed at least partially over the surface of the substrate.

19. A photovoltaic cell, comprising a photovoltaic cell element according to claim 18 and a first electrically-conductive structure located over a first surface of the substrate and a second electrically-conductive structure located over a second surface of the substrate opposite to the first surface.
